(19) United States
(12) Patent Application Publication
(10) Pub. No.: US 2002/0152757 A1
(43) Pub. Date: Oct. 24, 2002

(54) Cooling exchanger

(76) Inventor: Tsung-Chih Chen, Taoyuan (TW)

Correspondence Address: DOUGHERTY & TROXELL, SUITE 1404, 5205 LEESBURG PIKE, FALLS CHURCH, VA, 22041, US

(21) Appl. No.: 09/836,192

(22) Filed: Apr. 18, 2001

(51) Int. Cl. F25B 21/02; H01L 35/28

(52) U.S. Cl. 62/3.7; 62/3.3; 136/204

(57) ABSTRACT

A cooling exchanger comprised of a cooling base plate, two units of water pans and two units of water pumps. Within, Said cooling base plate include two units of contact plats incorporated with multiple units of SbBi crystals and bridged with a conductor. Outer edges between said two contact plates are coated with insulation resin to close and separate a shortage. A DC source is connected to said two units of SbBi crystal containing opposite polarities connected and a relative temperature difference (ΔT) takes place at where both contact plates connected to the crystals. Said two units of water pan are locked in position on two contact plates of the cooling base plate. A water inlet and a water outlet provided on the front of each eater pan are respectively connected to form a close pipeline for the water controlled by a water pump to circulate inside the pipeline. The water from the pipeline flows into said two water pans to complete heat exchange for being subject to the temperature difference (ΔT) to reduce the temperature of the circulating water for achieving the purpose of lowering the room temperature.

### BACKGROUND OF THE INVENTION

(a) Field of the Invention

The present invention relates to a cooling exchanger, and more particularly to one provide heat exchange to be applied in an air conditioning system to replace its cooling exchanger for compressor and coolant.

(b) Description of the Prior Art

As the global temperature rises by year due to green house effect, traditional electric fans fail to lower the ambient temperature in summer and air conditioner becomes a must either at home or in public place. FIG. 1 of the accompanying drawings shows a traditional air conditioner adapted with a compressor 6 to compress coolant to circulate in coils 2, 2′ for heat exchanging and for the coolant to absorb the heat. However, heat exhaust from the coolant tends to deteriorate the green house effects, making the global hotter in long run. Therefore, it is a common effort of the world to control the green house effects and protect our ecology environment.

### SUMMARY OF THE INVENTION

The primary purpose of the present invention is to provide a cooling exchanger for industrial application to replace the compressor and coolant used in the traditional air conditioning system without compromising its cooling effect. To achieve this, a DC source is supplied to a cooling base plate to cause its both contact surfaces creating a temperature difference (ΔT). That is, if the temperature on either contact surface is approximately 50° C., the temperature on the other contact surface is about −10° C. (with a ΔT of 60° C.). Each contact surface of the cooling base plate is connected to a closed water pan provided with a water inlet and a water outlet. Pipeline of both front and rear coils of the air conditioner is connected to said water inlet and water outlet to provide heat exchange through a circulation water current created inside the pipeline for the thermal energy absorbed by both coils to reduce the ambient temperature.

### BRIEF DESCRIPTION OF THE DRAWINGS

FIG. 1 is a schematic view showing internal components in a prior art of air conditioning system.

FIG. 2 is a schematic view showing members related to a cooling exchanger of the present invention.

FIG. 3 is a side view of the cooling exchanger of the present invention.

FIG. 4 is a schematic view showing members related to a cooling base plate of the present invention.

FIG. 5 is a schematic view showing members related to a coil in an air conditioning system of the present invention.

FIG. 6 is a schematic view showing a preferred embodiment of the present invention in the air conditioning system.

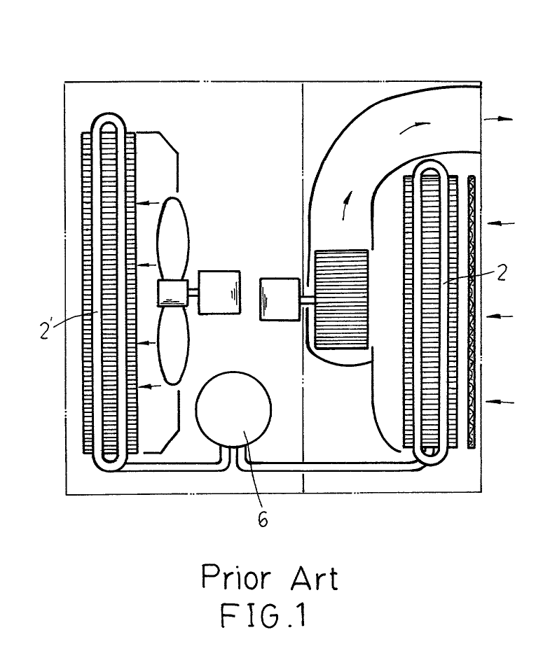

### DETAILED DESCRIPTION OF THE PREFERRED EMBODIMENTS

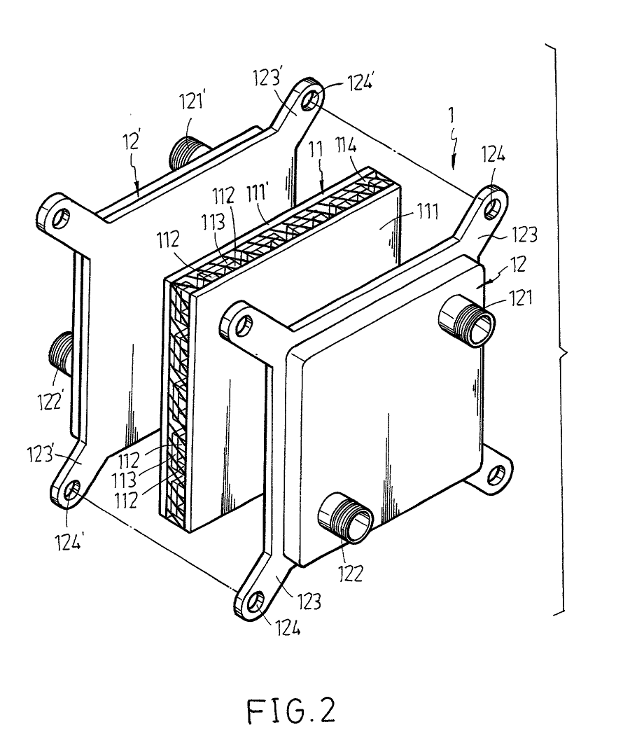

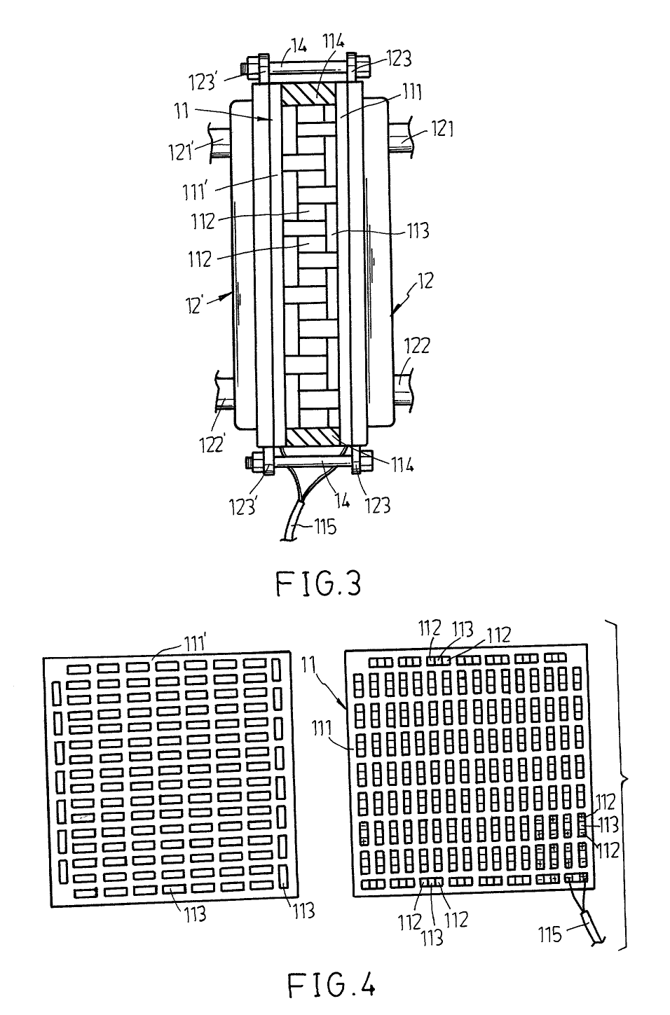

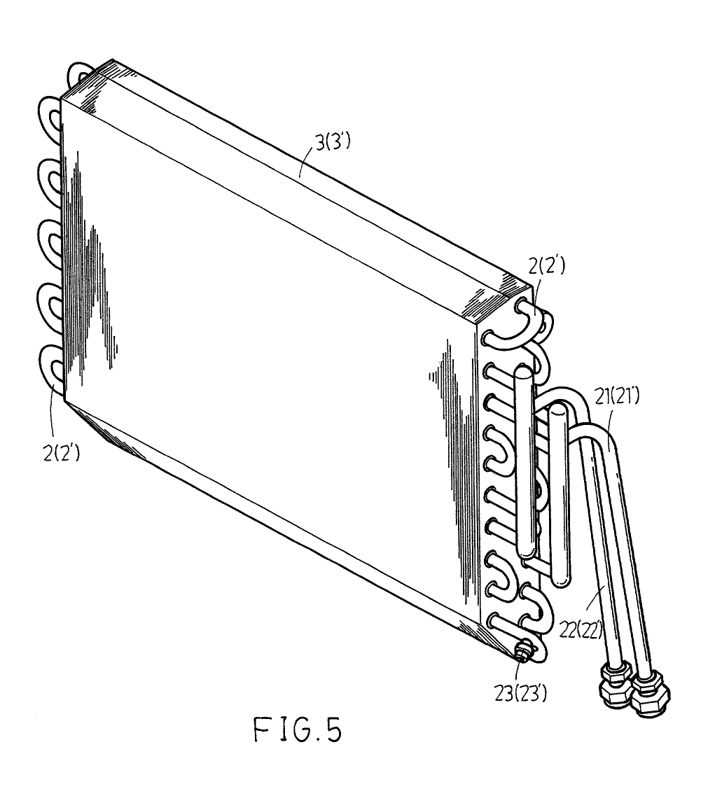

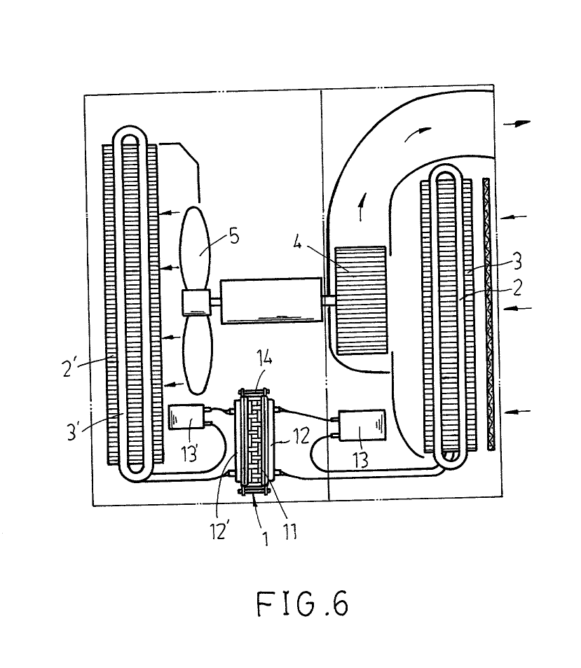

Referring to FIGS. 2 through 6, a cooling exchanger 1 of the present invention is essentially comprised of a cooling base plate 11, two units of water pan 12, 12′, and two units of water pump 13, 13′. Wherein, the cooling base plate 11 is comprised of two contact plates 111, 111′ connected between by a multiple of SbBi crystal 112 and is conducted by a bridge conductor 113. Outer edge between said two contact plates 111, 111′ is enclosed with an insulation resin 114 to form an isolated short circuit. Two units of SbBi crystal 112 having opposite polarities are respectively connected to a positive electrode and a negative electrode of a DC power line 115. A temperature difference (ΔT) is created between both contact plates 111, 111′ connected to those SbBi crystals 112 once they are conducted with the direct current. That is, by controlling the conduction time, the temperature on one contact plate 111 indicates a comparative lower temperature in relation to that of the other contact plate 111′. Therefore, a temperature difference (ΔT) is created between two said contact plates 111, 111′.

Said two water pans 12, 12′ each related to a hollow container. A water inlet 121 (121′) and a water outlet 122 (122′) are provided on the front of the water pan 12 (12′). A bolting hole 124 (124′) is each provided at a plate 123(123′) protruding from each comer of the water pan 12 (12′). Both of said water pans 12, 12′ are abutted back to back onto the contact plates 111, 111′ of the cooling base plate 11 and locked in position using a fastening element 14 inserted through said bolting holes 124, 124′ of the corresponding protruded plates 123, 123′. Therefore, both units of water pans 12, 12′ are respectively secured on the contact plate 111, 111′ of the cooling base plate 11. Furthermore, said water inlets 21, 21′ from the coils 2, 2′ are respectively connected to a drain pipeline from the water pumps 13, 13′ while said water outlets 122, 122′ are respectively connected to the water inlet 21, 21′ to the coils 2, 2′. Both of the water outlets 122, 122′are respectively connected to water inlets 21, 21′ of the coils 2, 2′. The pipeline of said water outlets 22, 22′ from the coils 2, 2′ are respectively connected to a suction of the water pumps 13, 13′ for the coils 2, 2′ to respectively form a closed pipeline with said two units of water pans 12, 12′ for water circulation.

When the cooling exchanger of the present invention is applied in the air conditioning system, the two water inlets 121, 121′ from said two units of water pans 12, 12′ are connected to the drain pipeline of the water pumps 13, 13′. Said two water outlets 122, 122′ are respectively connected to the water inlets 21, 21′ of the coils 2, 2′ so that both said coils 2, 2′ respectively form a closed pipeline with said water pans 12, 12′ for water to circulate. A drain valve 23 (23′) is provided to the lowest pipeline at the base of said coil 2 (2′) to facilitate filling and drainage of water inside the pipeline for service purpose. An eccentric fan 4 provided in the air conditioning system draws the hot air in the room for convection. The hot air pass through multiple heat sinks 3 cladding the coil 2 for heat exchange and a blade fan 5 blows the hot air inside the air conditioning system outside the room. By convection, multiple heat sinks 3′ cladding the coil 2′ absorb the hot air for exchange. Therefore, the hot air absorbed by said heat sinks 3, 3′ pass through and carried out by the water circulating in the coils 2, 2′ and engage in heat exchange with the cooling base plate 11 through the water pans 12, 12′ to reduce the temperature of the circulating water. The temperature of the water flowing through the water pan 12 is particularly reduce to a lower extent due to the presence of ΔT before returning to the coil 2 to reduce the temperature of the heat sinks 3. The ambient air drawn by the eccentric fan 4 and flowing through the heat sink 3 completes heat exchange to bring down the temperature of the air in the room.

The cooling exchanger of the present invention is capable of replacing the compressor and coolant installed in a traditional air conditioning system without compromising its cooling effects. In addition, for economic benefit, the conversion of electric power into air freezing energy helps saving the higher energy cost without damaging the ecology.

What the invention claimed is:

1. A cooling exchanger comprised of a cooling base plate, two units of water pans and two units of water pumps characterized by that:
Said cooling base plate having two units of contact plats incorporated with multiple units of SbBi crystals and bridged with a conductor;
Outer edges between said two contact plates coated with insulation resin to close and separate a shortage;
Two units of said SbBi crystal containing having opposite polarities connected to a DC source and both contact plates connected to it having relative temperature difference (ΔT);
Said two units of water pans each being a hollow container;
The front of the water pan has a water inlet and a water outlet;
Four comers of the water pan having a protrusion of a bolting hole;
The bolting hole having a locking member to pass through to hold it in position;
Both of said water pans mutually held in position on the contact plate of the cooling base plate;
A pipe each connecting the water inlets and the water outlets from said two units of water pans to form a closed pipeline;
Water controlled by a water pump circulating in said closed pipeline; and
The water from the closed pipeline flowing into said two units of water pans and completing heat exchange subject to the temperature difference (ΔT) of the cooling base plate to reduce the temperature of the water circulating in the water pans.
